(19) United States
(12) Patent Application Publication
(10) Pub. No.: US 2022/0357386 A1
(43) Pub. Date: Nov. 10, 2022

(54) ARC DETECTION AND RECORDING IN ELECTRIC TRAINS, SUBWAYS, STREETCARS AND BUSSES

(71) Applicant: MERSEN USA EP CORP., Boonton, NJ (US)

(72) Inventor: Roy A. Ball, Coral Springs, FL (US)

(73) Assignee: MERSEN USA EP CORP., Boonton, NJ (US)

(21) Appl. No.: 17/737,252

(22) Filed: May 5, 2022

Related U.S. Application Data
(60) Provisional application No. 63/185,652, filed on May 7, 2021.

(51) Int. Cl. G01R 31/12; G01R 31/00; G01S 19/01; B60L 3/12; B61L 27/57; B61L 25/02

(52) U.S. Cl. CPC G01R 31/1218; G01R 31/006; G01S 19/01; B60L 3/12; B61L 27/57; B61L 25/025; B60L 2200/26; B61C 3/00

(57) ABSTRACT

A device and method for detecting a location of an arc event between a power bus and a coupler of an electric vehicle monitors an interface between the power bus and the coupler for the occurrence of an optical event. A determination is made if an arc event occurred based on the optical event, and upon determining the occurrence of an arc event at least one of a time the arc event occurred or a position of the electric vehicle at the time the arc event occurred is recorded.

### RELATED APPLICATION DATA

This application claims priority of U.S. Provisional Application No. 63/185,652 filed on May 7, 2021, which is incorporated herein by reference in its entirety.

### FIELD OF THE INVENTION

The invention relates generally to arc faults and, in particular, to methods and systems for detecting arc faults in vehicles that are electrically powered by an external voltage source.

### BACKGROUND OF THE INVENTION

Electric vehicles such as trains, subways, streetcars and electric busses are often powered by an external voltage source, such as an AC or DC power source, that is provided via a power bus. For some electric vehicles (e.g., subways and some trains) the power bus is in the form of a third electrically-energized rail, as shown in FIGS. 1A and 1B. More specifically, a rail system 10 includes ground rails 12, which support and guide the electric vehicle along the rail system, and a power rail 14 that supplies power to the electric vehicle. The electric vehicle derives power from the power rail 14 via a rail connection means 16, such as a collector shoe, which is slidingly coupled to the power rail 14.

For other electric vehicles (e.g., streetcars, some trains, electric busses) the power bus may be in the form of an overhead power line 20, as shown in FIGS. 2A and 2B. Electric vehicles that collect their power from overhead lines 20 use an overhead connection means 22, such as a pantograph, bow collector or trolley pole to contact the power line.

Regardless of the power type (AC or DC) or the way in which the power is provided, (third rail or overhead), there is a connection made to the power bus that provides an electrical current path to the vehicle's propulsion motor(s). In normal operation, minimal arcing is produced between the power bus and the connection means. However, if arcing is excessive then the interface between the connection means and the power bus can quickly degrade. Most often the excessive arcing between the connection means and the power bus is an issue with the surface of the power bus.

When the power bus surface is suspected of having excessive wear, maintenance must be performed on the power bus. An issue with repairing the power bus, however, is that the location of the portion that requires maintenance is unknown, and finding this location can be problematic. The vehicle may have travelled hundreds of kilometers and the section of power bus that needs attention may not be visible at first glance.

### SUMMARY OF THE INVENTION

Aspects of the invention are directed to a means for detecting excessive arcing between a power bus and a connection means of an electric vehicle, such as a train, subway, streetcar, bus, or other like electric vehicle and recording the arcing event. The information recorded during the arcing event may be used to identify the exact section of power bus that needs attention.

According to one aspect of the invention, a method for detecting a location of an arc event between a power bus and a power coupler of an electric vehicle includes: monitoring an interface between the power bus and the power coupler for the occurrence of an optical event; determining the occurrence of an arc event based on characteristics of the optical event; and upon determining the occurrence of an arc event, recording at least one of a time the arc event occurred or a position of the electric vehicle at the time the arc event occurred.

In one embodiment, monitoring the interface includes obtaining optical data of the interface.

In one embodiment, monitoring the interface includes obtaining optical data from a plurality of optical sensors, wherein each optical sensor has a different field of view from other optical sensors of the plurality of optical sensors.

In one embodiment, determining includes filtering the optical data; and using the filtered data to detect the occurrence of the arc event.

In one embodiment, filtering includes comparing a time required for the optical event to reach a maximum intensity (rise time), and concluding an arc event has not occurred when the time required to reach maximum intensity is greater than a predetermined time period.

In one embodiment, a first sensor of the plurality of sensors has a direct or complete view of the interface and other sensors of the plurality of sensors have a partial or indirect view of the interface, and filtering further includes concluding an arc event has occurred if the time required to reach maximum intensity is less than a predetermined time period and the an amplitude of light detected by the first sensor is greater than an amplitude of light detected by the other sensors, and concluding an arc event has not occurred if the time required to reach maximum intensity is greater than the predetermined time period or the amplitude of light detected by the first sensor is less than an amplitude of light detected by the other sensors.

In one embodiment, filtering includes determining an origin of the optical event based on a comparison of light intensity detected by each sensor, and concluding an arc event has not occurred when the origin does not correspond to the interface.

In one embodiment, filtering includes determining an intensity of the optical event detected by each sensor; comparing the intensity of the optical event as detected by each sensor to predetermined thresholds; and concluding an arc event has not occurred when the intensity does not fall within a prescribed intensity range.

In one embodiment, a first sensor of the plurality of sensors has a direct or complete view of the interface and other sensors of the plurality of sensors have a partial or indirect view of the interface, and filtering includes concluding an arc event has not occurred if an amplitude of light detected by the first sensor is less than an amplitude of light detected by the other sensors.

In one embodiment, filtering includes comparing a duration of the optical event to a predetermined duration, and concluding an arc event has not occurred when the duration of the optical event is outside a predetermined time period.

In one embodiment, filtering includes excluding optical data obtained for predetermined locations of the vehicle.

In one embodiment, recording a position of the electric vehicle comprises recording coordinates at which the arc event occurred.

In one embodiment, recording coordinates includes using a geographic positioning system (GPS) to obtain the coordinates of the electric vehicle.

In one embodiment, recording a position of the electric vehicle comprises recording a specific segment of the power bus at which the arc event occurred.

In one embodiment, recording a position of the electric vehicle comprises recording a linear distance between two stations.

According to another aspect of the invention, a system for detecting a location of an arc event between an electric power bus and a power coupler of an electric vehicle operatively coupled to the power bus includes: a sensor module including at least one sensor configured to obtain optical data; and a processing module communicatively coupled to the sensor module, the processing module including logic configured to carry out the method as described herein.

In one embodiment, the at least one sensor includes an optical sensor.

In one embodiment, the at least one sensor includes a plurality of optical sensors, at least one of the optical sensors having a direct view of an interface between the power bus and the power coupler, and at least one other sensor having a partial or indirect view of the interface between the power bus and the power coupler.

According to another aspect of the invention, an electric vehicle includes the system as described herein.

In one embodiment, the electric vehicle comprises one of a bus, train, or street car.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The invention may take physical form in certain parts and arrangement of parts, an embodiment of which is described in detail in the specification and illustrated in the accompanying drawings, wherein:

FIG. 1A illustrates an exemplary power system that employs a third rail as a power bus.

FIG. 1B illustrates a coupling means for electrically connecting a vehicle to the third rail of FIG. 1A.

FIG. 2A illustrates an exemplary power system that employs an overhead conductor as a power bus.

FIG. 2B illustrates a coupling means for electrically connecting a vehicle to the overhead conductor of FIG. 2A.

FIG. 3 illustrates an exemplary system for detecting and recording arc faults in accordance with an embodiment of the invention.

FIG. 4 is a block diagram illustrating components of the system for detecting and record arc faults in accordance with an embodiment of the invention.

FIG. 5 is a flow chart illustrating exemplary steps of a method for recording arc faults in accordance with an embodiment of the invention.

FIG. 6 is a flow chart illustrating exemplary steps of detecting an arc fault in accordance with an embodiment of the invention.

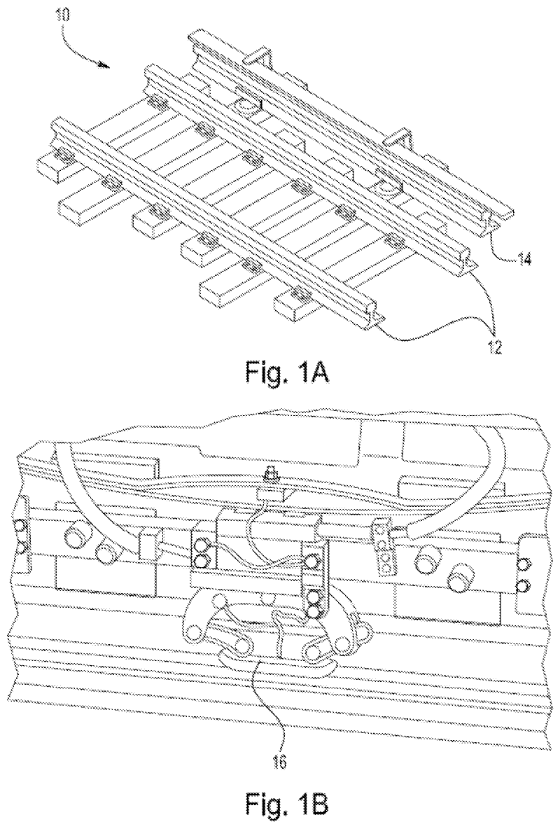

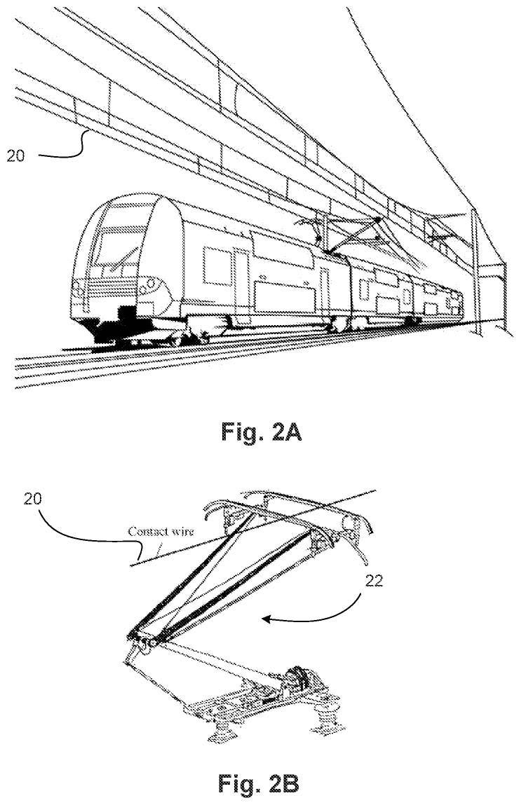

### DETAILED DESCRIPTION OF THE INVENTION

Embodiments of the present invention will now be described with reference to the drawings, wherein like reference numerals are used to refer to like elements throughout. It will be understood that the figures are not necessarily to scale.

Electrically powered vehicles, such as trains, streetcars, subways, busses and the like, obtain electric power from a remote power source though an electrical connection to a power bus. This power bus may be in the form of a third rail or an overhead cable, whereby the vehicle includes a connection means to electrically couple to the power bus. As discussed above, arcing between the connection means and the power bus can occur as the power bus wears due to friction caused by the sliding action of the connection means over the power bus. Due to the linear length of the power rail of a mass transportation system, it can be difficult to identify the portion of the power bus that requires maintenance.

A device and method in accordance with the invention monitors for excessive arcing between the power bus and the connection means of the electrically-powered vehicle. Upon such arcing exceeding a prescribed threshold, the device and method in accordance with the invention record the arcing event. Such recording can include an intensity and/or duration of the arcing event, the time and date of the arcing event, and a location along the power bus at which the arcing event occurred (e.g., the specific coordinates at which the arcing occurred or a general location along a specific segment of the power bus). Such coordinates may include a linear distance between stations, GPS coordinates, or any means for identifying a location of the arc event along the power bus.

The arcing event may be detected by means of optical sensors, whereby one or more optical sensors monitor the interface between the power bus and the vehicle's connection means. As used herein with respect to the power bus and connection means, the term “interface” refers to the electrical connection between the power bus and the connection means. Image data collected by the one or more optical sensors is analyzed and compared to threshold data to determine if an arc of sufficient intensity has occurred. If the arc is of sufficient intensity, then the time, date and/or location of the vehicle is recorded and a flag is set to alert maintenance personnel of a possible wear issue with the power bus.

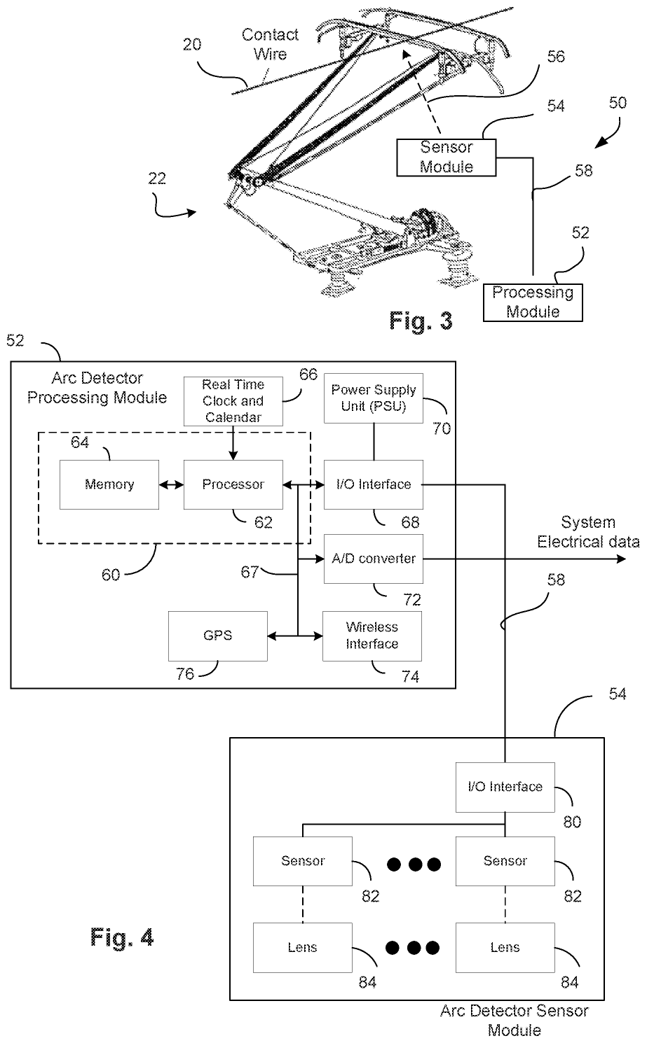

Referring now to FIG. 3, illustrated is an exemplary arc detection system 50 in accordance with an embodiment of the invention. FIG. 3 illustrates the arc detection system 50 in the context of an overhead power bus. It should be appreciated, however, that the arc detection system 50 is also applicable to a power bus that employs a third rail power bus by simply directing field of view of the sensor module in the direction at the interface between the power rail and the connection means.

The arc detection system 50 includes an arc detection processing module 52, which may be located anywhere on the vehicle. Preferably, the processing module 52 is located inside the vehicle to shield it from the external environment. However, it is also possible to locate the processing module outside the vehicle, e.g., on a roof of the vehicle, under the vehicle, etc. The processing module 52 is communicatively coupled to a sensor module 54, for example, via a serial communication link, wireless link, or the like. Preferably, the sensor module 54 is located as close as is practical to the arc source, i.e., the interface between the connection means and the power bus. As will be discussed in further detail below, the sensor module 54 includes optical sensors that have direct and/or indirect line of sight 56 to the interface between the connection means and the power bus to enable the sensor module 54 to optically monitor for the occurrence of an arc. Data collected by the sensor module 54 is communicated to the processing module 52, which analyzes the data to determine if an arc of sufficient intensity is present, and if so records location data and other data for later analysis.

With additional reference to FIG. 4, illustrated is an exemplary arc detector processing module 52 and an arc detector sensing module 54 in accordance with an embodiment of the invention. While the embodiment of FIG. 4 utilizes two separate modules, it is contemplated that the functionality of both modules could be incorporated into a single module. The arc detector processing module 52 and/or the arc detector sensing module 54 may be portable to facilitate movement between vehicles.

The processing module 52 may include a primary control circuit 60 that is configured to carry out overall control of the functions and operations of the processing module 52. The control circuit 60 may include a processing device 62, such as a central processing unit (CPU), microcontroller or microprocessor, and memory 64. A real time clock and calendar 66 is coupled to the control circuit 60 to provide clocking. timing and time/date stamp functions. The processing device 62 executes code stored in memory 64 within the control circuit 60 and/or in a separate memory, in order to carry out operation of the processing module 52. For instance, the processing device 62 may execute code stored in memory 64 that implements the arc detection function as described herein. The memory 64 may be, for example, one or more of a buffer, a flash memory, a hard drive, a removable media, a volatile memory, a non-volatile memory, a random access memory (RAM), or other suitable device. In a typical arrangement, the memory 64 may include a non-volatile memory for long-term data storage and a volatile memory that functions as system memory for the control circuit 60. The memory 64 may exchange data with the processing device 62 over a data bus 67. Accompanying control lines and an address bus also may be present.

The processing module 52 may further include one or more input/output (I/O) interface(s) 68. The I/O interface(s) 68 may be in the form of typical I/O interfaces and may include one or more electrical connectors, USB connectors, etc. The I/O interface(s) 68 may form one or more data ports for connecting the processing module 52 to another device (e.g., a computer) or to the sensor module 54 via cable 58. Further, operating power may be received over the I/O interface(s) 68 as well as power to charge a battery of a power supply unit (PSU) 70 of the processing module 52. The PSU 70, which may include an on/off switch (not shown) supplies power to operate the processing module 52.

The processing module 52 also may include various other components. For instance, an analog-to-digital converter 72 may be used to collect electrical data from the vehicle, such as voltage, current, etc. A local wireless interface 74, such as RF transceiver may be used to establish communication with a nearby device, such as a user terminal or the sensor module 54. Additionally, a GPS module 76 can be included to provide location data to the control circuit 60 to identify a location (e.g. GPS coordinates) at which an arc event is detected. In the illustrated embodiment the GPS module 76 is integrated into the processing module 52. However, the GPS module 76 may be a separate module that is communicatively coupled to processing module 52 via the I/O interface 68, e.g., via a USB connection.

With continued reference to FIGS. 3 and 4, the sensor module 54 includes I/O interface 80, which may be in the form of typical I/O interfaces and may include one or more electrical connectors, USB connectors, etc. In the illustrated embodiment the sensor module 54 communicates with the processing module 52 via the I/O interface 80 through cable 58, and also may receive electrical power from the processing module 52 via the cable 58 and I/O interface 68 of the processing module. Communicatively coupled to the I/O interface 80 of the sensor module 54 is one or more sensors 82, such as optical sensors. Suitable optical sensors include Melexis, MLX75305KXD-ABA light sensors.

Some of the often optical sensors may be located at a location at which the respective sensor can measure reflected light that bounces off surfaces in the area of the arc. Each time the light bounces off a surface the light amplitude decreases and thus if the light reflects from more than one surface detection reliability may decrease. The sensor works well if it has direct view of the detected light, or if the sensor detects the first time the light is reflected (the first reflection).

In one embodiment, four such sensors may be arranged 90 degrees in rotation apart from the adjacent sensor along a fixed plane, whereby the sensors 82 have a direct view of the arc source or an indirect view of the arc source. As will be appreciated, more or fewer sensors may be employed depending on the requirements of the specific application. Regardless of whether a sensor has a direct or indirect view of the arc source, the sensor should be positioned such that it can sense at least a first reflection of the arc in order to distinguish the arc flash from other sources of light. A first reflection refers to light generated by the arc that has been reflected from only one surface.

Multiple sensor views can assist in distinguishing an arc flash from other sources of light. Lens 84 collects light from the arc flash and provides the collected light to the sensor 82 (each sensor 82 may have a lens 84 dedicated to that sensor).

The sensor of the one or more sensors pointed in the direction of the arc source is referred to as the primary sensor. In operation, light detected by the one or more sensors 82 is converted into an electrical signal proportional to the amplitude of the light. The signal from the one or more sensors 82 is digitized by an analog-to-digital converter and provided to the processing module 52 through I/O interfaces 80, 68 and cable 58. Based on the light amplitude detected by each of the one or more sensors 82 and the known direction in which the one or more sensors 82 is oriented (the direction of each sensor may be stored in memory of the processing module 52), the control circuit 60 can determine the azimuth of the light source. For example, the magnitude of each sensor is measured and the sensor(s) with highest amplitude of light indicates the direction of light source.

While a single sensor may be utilized, the use of multiple sensors can minimize false arc detections. For example, as an arc occurs the primary sensor (which is pointed at the arc source) will detect and transmit the highest amplitude signal relative to the other sensors (which are not pointing at, or not directly pointing at, the arc source). If any sensor other than the primary sensor (i.e., sensors not pointed at the arc source) detects and transmits a higher amplitude signal than the primary sensor, then the light event is ignored as it did not originate at the arc source.

The control circuit 60 may examine the time for the detected light to increase to maximum amplitude (the rise time). The rise time in combination with the direction of the light can provide a reliable indicator of an arc event. In this regard, a change in intensity can be measured by digitizing the voltage output of each sensor 82, and translating the voltage output into a rise-time value that can be compared to known rates stored in memory to determine if the data corresponds to an actual arc event.

While the above filtering method can provide a reliable indication of an arc event, certain types of light events, e.g., an LED light switched on while pointed directly at the primary sensor, may still trigger an arc event as the rise time of such light is in the single digit microsecond range. To further enhance the filtering process and reduce/eliminate false arc events, a time period of the arc pulse can be measured and those that exceed a prescribed time period can be excluded. An arc is a fast event, although some sparks may persist but at a lower amplitude. Thus, arc events that exceed a predetermined time span can be excluded as false positives.

Also, the power bus for trains, subways, streetcars and electric busses often has thermal expansion joints and/or locations where the power sources change to a different circuit. At these locations arcs may occur as part of normal operation. These arcs, however, are lower in light amplitude than the more destructive arcs that the system seeks to detect. To remove false triggering from these “junction” arcs, a threshold can be implemented in which events below the threshold are ignored. Additionally or alternatively, the location of the expansion joints may be known, for example, based on GPS coordinates, and arcs that occur at these coordinates can be ignored.

For example, in a four light sensor embodiment one sensor is a primary sensor (the sensor with a direct view of the interface between the power bus and connection means) and three sensors are secondary sensors (sensors that may have only a partial or indirect view of the interface between power bus and coupling means). Each sensor may be connected to its own analog-to-digital converter that digitizes the signal, e.g., at a rate of about 50,000 times per second, once every 20 microseconds. For each sensor, two running averages are continuously calculated (continuously meaning the averages are recalculated with each analog-to-digital conversion), and the difference in the magnitude for each sensor's long time and short time averages indicate the risetime for that sensor. All four conversions complete at the same time, and the two averages for each sensor are as follows:
One long-time average light amplitude, which is the average of about 20 of the most recent analog-to-digital conversions, forms the baseline average that represents the light amplitude from a light sensor over several hundred microseconds. In the exemplary embodiment, the long-time average is the average light amplitude over a period of about 400 microseconds.
One short-time average light amplitude, which is the average of a small number (e.g., about 3) of the most recent analog-to-digital conversions, is in the tens of microseconds range. In the exemplary embodiment, the short-time average is the average light amplitude over a period of about 60 microseconds. (In the event of a fast and high amplitude arc flash a single conversion can cause the short time average to rise enough to trigger an arc event.)

Once all averages for all four sensors are calculated, the two averages from the primary sensor are examined. If the short-time average light amplitude for the primary sensor is close to the long-time average light amplitude for the primary sensor then no action is taken. If the two averages are different (e.g., if the short time average exceeds the long time average by a predetermined threshold value, which may be determined empirically), then further analysis is performed to determine the rate of rise of the signal. For example, if an arc causes a sudden flash of light then a sharp increase in the analog-to-digital conversion value is seen for the primary sensor “seeing” the light. The short-time average light amplitude will rise quickly, and the long-time average light amplitude will rise as well but slower. By subtracting the long-time average light amplitude from the short-time average light amplitude the rate of rise (rise time) for the light amplitude can be approximated.

At this point for the arc event to be considered as an actual event the light rise time and light amplitude thresholds must be exceeded. A fast rise time for the light (e.g., a slope less than 100 microseconds) will differentiate the light source from a non-arc event and the light amplitude indicates the severity of the arc event. For an arc event the rise-time of the light and the magnitude of the short-time average above the long-time average must exceed rise-time threshold (when an arc occurs the short time average will rise well above the longtime average). Next, the peak amplitude between the short-time average light amplitude above the long-time average light amplitude must exceed a light amplitude threshold. It may take multiple analog-to-digital conversions before the peak light amplitude is identified.

Once the rise-time and amplitude criteria are satisfied, then the direction of the flash is verified to ensure the event is a valid arc event. The short-time average light amplitude for each of the other three sensors can be examined relative to the short-time average light amplitude for the primary sensor to ensure the primary sensor has the highest magnitude. The sensor with the highest magnitude will indicate the light direction, which for a valid arc should be the primary sensor. If the primary sensor does not have the highest magnitude, then it can be concluded that an arc event has not occurred.

Finally, when the rise time for the primary sensor exceeds a threshold a timer is started. When the light detected by the primary sensor drops back below the threshold the timer is stopped. The timer value then is compared to a fixed length time to check that the period of time of the arc event did not exceed a prescribed time period. If the timer exceeds the prescribed time period it can be concluded an arc event has not occurred. The intent of using a timer is to filter out very bright sources that could be mistaken as an arc. For example, as a train exits a tunnel on a bright sunny day the sensor may be illuminated with sun light. In this scenario it is likely the sensor will stay illuminated for several hundred microseconds, which is substantially longer that an arc. This filtering function reduces the risk of false detections.

If the above light rise time, peak amplitude, flash direction and event length steps are satisfied, then it is concluded an arc has occurred and an event record is generated.

The event record can include a peak value for each sensor 82 taken at the time when the rise time qualified as a valid arc, along with date/time in which the event was detected. Additionally, a location of the vehicle at which the arc event is detected can be recorded based on GPS coordinates. If GPS data is not available (which may be typical for a subway), the time stamp can be compared to known route information to estimate the location of the arc event. The event record can be stored in non-volatile RAM and remain there until erased by maintenance personnel. The event record can be retrieved by a PC, laptop or other electronic maintenance device, through the USB port or via wireless means (e.g., Bluetooth, Wi-Fi, etc.)

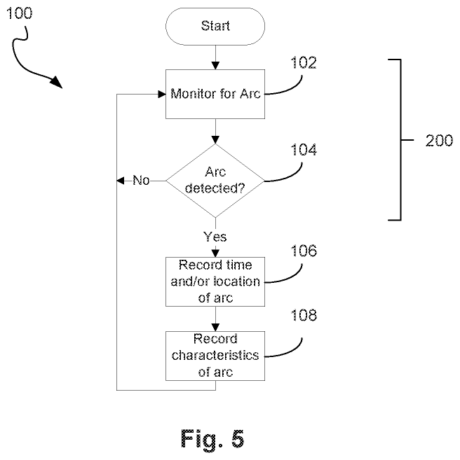

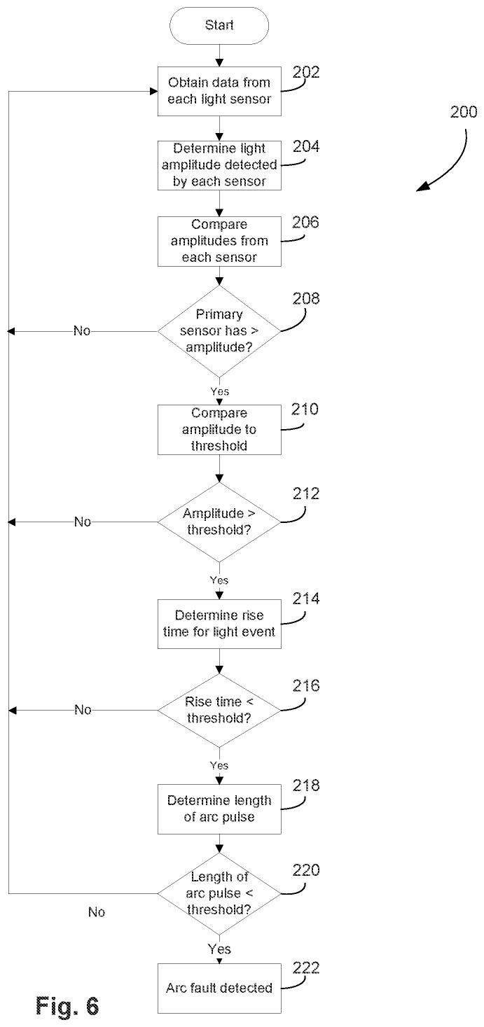

Referring to FIGS. 5 and 6, illustrated are exemplary methods 100 and 200 for detecting the location of excessive arcs in an electric transportation system in accordance with the invention. Variations to the illustrated methods are possible and, therefore, the illustrated embodiment should not be considered the only manner of carrying out the techniques that are disclosed in this document. Also, while FIGS. 5 and 6 show a specific order of executing functional logic blocks, the order of executing the blocks may be changed relative to the order shown and/or may be implemented in an object-oriented manner or a state-oriented manner. In addition, two or more blocks shown in succession may be executed concurrently or with partial concurrence. Certain blocks also may be omitted. The exemplary method may be carried out by executing code stored by an electronic device, such as the processing module 52 and/or the sensor module 54. The code may be embodied as a set of logical instructions that may be executed by a processor. Therefore, the methods may be embodied as software in the form of a computer program that is stored on a computer readable medium, such as a memory.

Beginning at step 102 of FIG. 5, the electrical coupling between the vehicle and the power bus is monitored to obtain data that is used to determine if an arc event has occurred. For example, the light intensity in a region of interest (the interface between the power bus and the coupling means) is monitored and data corresponding to that light intensity is collected. At step 104 a determination is made if an arc event has occurred. For example, the light data collected at step 102 can be analyzed for rapid changes in light intensity (rise time), the magnitude of the light intensity, the duration of the light event and the location of the light intensity. The location, rise time, magnitude and duration of the event can be used to conclude if an actual arc event has occurred or if the data corresponds to something other than an arc event. If it is concluded that an arc event did not occur, the method moves back to step 102 and repeats. Further details regarding steps 102 and 104 are discussed below with respect to FIG. 6.

If at step 104 it is concluded that an arc event did occur, then at step 106 the time, date and/or location (e.g., GPS coordinates) are recorded and stored in memory 64 for later retrieval. Optionally, at step 108 other data corresponding to the arc event may be recorded. For example, the current and voltage at the vehicle, the duration of the arc event, the number of arc events, etc. may be recorded and associated with the particular arc event. As will be appreciated, other data may be recorded depending of the specific application. Upon completing step 108, the method may move back to step 102 and repeat.

Moving now to FIG. 6, illustrated are additional details for steps 102 and 104 of FIG. 5. Beginning at step 202, the data from each light sensor is obtained by the processing module 52 from the sensor module 54. As previously discussed, the sensors 82 monitor the area of interest (i.e., the interface between the connection means and the power bus) to obtain a measurement of the intensity of light in the area of interest. The measurement is digitized and provided to the processing module 52 for further analysis. At step 204, the processing module 54 determines an amplitude of the light from each sensor. In this regard, the digitized data provided by each sensor 82 may be scaled and filtered to represent the amplitude of light detected by each respective sensor.

Next at step 206 the amplitude of light as detected by each sensor are compared to each other, and at step 208 it is determined if the primary sensor has detected light of highest amplitude. Since the primary sensor is directly monitoring the area of interest, for a true arc fault the primary sensor should detect light having the highest amplitude, as the other sensors have an indirect or partial view of the area of interest (and thus would not be subjected to the same light intensity as the primary sensor). If at step 208 the amplitude of light as detected by the primary sensor is not greater than the amplitude of light detected by the other sensors, then it can be concluded that an arc fault did not occur and the method moves back to step 202 and repeats. However, if the amplitude of light detected by the primary sensor is greater than the amplitude of light detected by the other sensors, then at step 214 the processing module 52 determines the rise time of the light event. The rise time is the time elapsed from the beginning of the light event until the light reaches a maximum amplitude Next at step 216 it is determined if the rise time is greater than a threshold time period. Arcs reach maximum intensity in a very short time (in the nanosecond range) and thus if the event has a slow rise time it can be concluded the event is not due to an arc fault. Accordingly, if the rise time is not greater than the threshold (i.e., the rise time is slow), then an arc fault has not occurred and the method moves back to step 202 and repeats. However, if the rise time is greater than the threshold time period (i.e., the rise time is fast), the method moves to step 218.

At step 218 the length of the arc pulse is determined. The length of the arc pulse may be regarded as the time the light is first detected until the light is no longer detected. An arc fault is a fast event and thus events that exceed a threshold time period can be excluded from being an arc fault. At step 220 it is determined if the length of the event is less than a threshold time period. If the event is not less than the threshold time period (i.e., the event is long), it is concluded an arc fault has not occurred and the method moves back to step 202 and repeats. However, if the event is less than the threshold time period the method moves to step 22 and an arc fault flag is set.

By using multiple filters (i.e., relative sensor amplitude, rise time, event duration), lighting events due to non-arc events can be ignored. As a result, accuracy of the arc fault detection is enhanced.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

1. A method for detecting a location of an arc event between a power bus and a power coupler of an electric vehicle, comprising:
monitoring an interface between the power bus and the power coupler for the occurrence of an optical event;
determining the occurrence of an arc event based on characteristics of the optical event; and
upon determining the occurrence of an arc event, recording at least one of a time the arc event occurred or a position of the electric vehicle at the time the arc event occurred.

2. The method according to claim 1, wherein monitoring the interface includes obtaining optical data of the interface.

3. The method according to claim 1, wherein monitoring the interface includes obtaining optical data from a plurality of optical sensors, wherein each optical sensor has a different field of view relative to other optical sensors of the plurality of optical sensors.

4. The method according to claim 1, wherein determining includes:
filtering the optical data; and
using the filtered data to detect the occurrence of the arc event.

5. The method according to claim 4, wherein filtering includes comparing a time required for the optical event to reach a maximum intensity (rise time), and concluding an arc event has not occurred when the time required to reach maximum intensity is greater than a predetermined time period.

6. The method according to claim 5, wherein a first sensor of the plurality of sensors has a direct or complete view of the interface and other sensors of the plurality of sensors have a partial or indirect view of the interface, and filtering further includes
concluding an arc event has occurred if the time required to reach maximum intensity is less than a predetermined time period and the an amplitude of light detected by the first sensor is greater than an amplitude of light detected by the other sensors, and
concluding an arc event has not occurred if the time required to reach maximum intensity is greater than the predetermined time period or the amplitude of light detected by the first sensor is less than an amplitude of light detected by the other sensors.

7. The method according to claim 4, wherein filtering includes determining an origin of the optical event based on a comparison of light intensity detected by each sensor, and concluding an arc event has not occurred when the origin does not correspond to the interface.

8. The method according to claim 4, wherein filtering includes:
determining an intensity of the optical event detected by each sensor;
comparing the intensity of the optical event as detected by each sensor to predetermined thresholds; and
concluding an arc event has not occurred when the intensity does not fall within a prescribed intensity range.

9. The method according to claim 4, wherein a first sensor of the plurality of sensors has a direct or complete view of the interface and other sensors of the plurality of sensors have a partial or indirect view of the interface, and filtering includes concluding an arc event has not occurred if an amplitude of light detected by the first sensor is less than an amplitude of light detected by the other sensors.

10. The method according to claim 4, wherein filtering includes comparing a duration of the optical event to a predetermined duration, and concluding an arc event has not occurred when the duration of the optical event is outside a predetermined time period.

11. The method according to claim 4, wherein filtering includes excluding optical data obtained for predetermined locations of the vehicle.

12. The method according to claim 1, wherein recording a position of the electric vehicle comprises recording coordinates at which the arc event occurred.

13. The method according to claim 12, wherein recording coordinates includes using a geographic positioning system (GPS) to obtain the coordinates of the electric vehicle.

14. The method according to claim 1, wherein recording a position of the electric vehicle comprises recording a specific segment of the power bus at which the arc event occurred.

15. The method according to claim 1, wherein recording a position of the electric vehicle comprises recording a linear distance between two stations.

16. A system for detecting a location of an arc event between an electric power bus and a power coupler of an electric vehicle operatively coupled to the power bus, comprising:
a sensor module including at least one sensor configured to obtain optical data; and
a processing module communicatively coupled to the sensor module, the processing module including logic configured to carry out the method according to claim 1.

17. The system according to claim 16, where the at least one sensor comprises an optical sensor.

18. The system according to claim 17, wherein the at least one sensor comprises a plurality of optical sensors, at least one of the optical sensors having a direct view of an interface between the power bus and the power coupler, and at least one other sensor having a partial or indirect view of the interface between the power bus and the power coupler.

19. An electric vehicle, comprising the system according to claim 1.

20. The electric vehicle according to claim 19, wherein the electric vehicle comprises one of a bus, train, or streetcar.
